(19) United States
(12) Patent Application Publication
(10) Pub. No.: US 2025/0044469 A1
(43) Pub. Date: Feb. 6, 2025

(54) METHOD AND SYSTEM FOR KINEMATICS-DRIVEN DEEP LEARNING FRAMEWORK FOR SEISMIC VELOCITY ESTIMATION

(71) Applicant: ARAMCO SERVICES COMPANY, Houston, TX (US)

(72) Inventors: Yong Ma, Katy, TX (US); Weichang Li, Katy, TX (US); Lei Fu, Houston, TX (US)

(73) Assignee: ARAMCO SERVICES COMPANY, Houston, TX (US)

(21) Appl. No.: 18/362,720

(22) Filed: Jul. 31, 2023

(51) Int. Cl. G01V 1/28; E21B 44/00; G01V 1/30; G06F 30/27

(52) U.S. Cl. CPC G01V 1/282; E21B 44/00; G01V 1/303; G06F 30/27; E21B 7/04; G01V 2210/645

(57) ABSTRACT

A system for enhancing traveltime information in a seismic dataset and determining a velocity model. The system includes a first initial velocity model, a forward modelling procedure, a machine-learned model, a drilling system with a wellbore planning system, and a computer. The computer is configured to: receive a non-synthetic seismic data set for a subsurface region of interest; perturb the first initial velocity model forming a first plurality of velocity models; simulate, with the forward modelling procedure, a first plurality of seismic data sets; form a first plurality of transformed seismic data sets with enhanced traveltime; train the machine-learned model using the first plurality of velocity models and the first plurality of transformed seismic data sets; transform the non-synthetic seismic data set to a non-synthetic transformed seismic data set; and process the non-synthetic seismic data set with the trained machine-learned model to predict a velocity model for the subsurface region.

### BACKGROUND

In the context of oil and gas exploration and production, a variety of tools and methods are employed to model subsurface regions and plan wellbore paths to extract desired hydrocarbons. An accurate seismic velocity model is critical for geophysical exploration and oil and gas field planning. Generally, layers of rock in the subsurface of the Earth are formed through deposits of sediment over time and under a variety of environmental conditions. As such, layers of rock may be composed of different constituents and may have different physical and/or chemical properties. In general, a velocity model maps the speed at which seismic waves travel through the subsurface. Consequently, a velocity model may be used, among other things, to identify the structure of the subsurface (e.g. the depth of subsurface formations) and identify the location of hydrocarbon reservoirs.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Embodiments disclosed herein generally relate to a method for determining a location of a hydrocarbon reservoir using a velocity model. The method includes obtaining a seismic data set for a subsurface region of interest and transforming the seismic data set to a transformed seismic data set, where traveltime information is enhanced in the transformed seismic data set. The method further includes processing the transformed seismic data set with a trained machine-learned model to predict a velocity model for the subsurface region of interest and determining the location of the hydrocarbon reservoir in the subsurface region of interest using the velocity model.

Embodiments disclosed herein generally relate to a computer-implemented method of training a machine-learned model that includes obtaining a first initial velocity model, perturbing the first initial velocity model to form a first plurality of velocity models, and using a forward model to simulate a first plurality of seismic data sets from the first plurality of velocity models. The method further includes transforming the first plurality of seismic data sets to form a first plurality of transformed seismic data sets, where traveltime information is enhanced in each of the transformed seismic data sets in the first plurality of transformed seismic data sets and training a machine-learned model using the first plurality of velocity models and the first plurality of transformed seismic data sets, where the machine-learned model is configured to accept transformed seismic data.

Embodiments disclosed herein generally relate to a system that includes a first initial velocity model, a forward modelling procedure, a machine-learned model, a drilling system with a wellbore planning system, and a computer with one or more computer processors and a non-transitory computer readable medium. In one or more embodiments, the computer is configured to: receive a non-synthetic seismic data set for a subsurface region of interest; perturb the first initial velocity model to form a first plurality of velocity models; use the forward modelling procedure to simulate a first plurality of seismic data sets from the first plurality of velocity models; transform the first plurality of seismic data sets to form a first plurality of transformed seismic data sets, where traveltime information is enhanced in each of the transformed seismic data sets; train the machine-learned model using the first plurality of velocity models and the first plurality of transformed seismic data sets, where the machine-learned model is configured to accept one or more transformed seismic data sets; transform the non-synthetic seismic data set to form a non-synthetic transformed seismic data set; and process the non-synthetic seismic data set with the trained machine-learned model to predict a velocity model for the subsurface region of interest.

Other aspects and advantages of the claimed subject matter will be apparent from the following description and the appended claims.

### BRIEF DESCRIPTION OF DRAWINGS

FIG. 1 depicts a seismic survey in accordance with one or more embodiments.

FIG. 2 depicts a drilling system in accordance with one or more embodiments.

FIG. 3A depicts an example seismic data set in accordance with one or more embodiments.

FIG. 3B depicts an example seismic data set in accordance with one or more embodiments.

FIG. 4 depicts a deep learning-based framework in accordance with one or more embodiments.

FIG. 5A depicts a seismic data set in accordance with one or more embodiments.

FIG. 5B depicts a transformed seismic data set in accordance with one or more embodiments.

FIG. 6 depicts a system in accordance with one or more embodiments.

FIG. 7A depicts a recurrent neural network in accordance with one or more embodiments.

FIG. 7B depicts an unrolled recurrent neural network in accordance with one or more embodiments.

FIG. 7C depicts a long short-term memory network in accordance with one or more embodiments.

FIG. 8 depicts a neural network in accordance with one or more embodiments.

FIG. 9 depicts a flowchart in accordance with one or more embodiments.

FIG. 10 depicts an instance of a machine-learned model in accordance with one or more embodiments.

FIG. 11A demonstrates machine-learned model predictions in accordance with one or more embodiments.

FIG. 11B demonstrates machine-learned model predictions in accordance with one or more embodiments.

FIG. 11C demonstrates machine-learned model predictions in accordance with one or more embodiments.

FIG. 12A demonstrates machine-learned model predictions where the machine-learned model is trained with and applied to untransformed seismic data sets.

FIG. 12B demonstrates machine-learned model predictions where the machine-learned model is trained with and applied to untransformed seismic data sets.

FIG. 12C demonstrates machine-learned model predictions where the machine-learned model is trained with and applied to untransformed seismic data sets.

FIG. 13 depicts a system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

It is to be understood that the singular forms “a,” “an,” and “the” include plural referents unless the context clearly dictates otherwise. Thus, for example, reference to “acoustic signal” includes reference to one or more of such acoustic signals.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowchart may be omitted, repeated, and/or performed in a different order than the order shown. Accordingly, the scope disclosed herein should not be considered limited to the specific arrangement of steps shown in the flowchart.

Although multiple dependent claims are not introduced, it would be apparent to one of ordinary skill that the subject matter of the dependent claims of one or more embodiments may be combined with other dependent claims.

Generally, layers of rock in the subsurface of the Earth are formed through deposits of sediment over time and under a variety of environmental conditions. As such, layers of rock may be composed of different constituents and may have different physical and/or chemical properties. Subsurface rock properties may be anisotropic. In order to describe and model a subsurface region of the Earth, a variety of data collection methods may be employed. These methods may include, but are not limited to: collecting data from one or more wells disposed throughout the subsurface, which may include subsurface logs and/or petrophysical logs; conducting a seismic survey; collecting data from previously drilled, nearby wells, sometimes called “offset” wells; and collecting so-called “soft” data, such as outcrop information and data describing analogous modern geological or depositional environments. The collected data may be used to construct, or otherwise inform, a subsurface model. Once constructed, subsurface models may include information about the spatial distribution of subsurface formation properties such as, but not limited to: porosity; mineral content; chemical makeup; and density. Additionally, the modeled subsurface region may include information about the subsurface formation geological unit thicknesses.

An accurate subsurface model is critical for geophysical exploration, such as the identification of reservoirs, and for oil and gas field planning and lifecycle management. One such subsurface model is a seismic velocity model (“velocity model”). A velocity model maps the speed at which seismic waves travel through the subsurface. Consequently, a velocity model may be used, among other things, to identify the structure of the subsurface (e.g., the depth of subsurface formations), to aid in imaging seismic pre-stack data, to monitor carbon dioxide (CO₂) distributions and retention, to identify the location of hydrocarbon reservoirs, and to plan wellbore paths. Further, a velocity model may be integrated with, or inform, other subsurface models. Typically, the velocity at which seismic waves travel through the subsurface cannot be directly measured. As such, a velocity model is generally constructed by processing recorded seismic data. Seismic data may be obtained through a seismic survey, which will be described in greater detail below. Processing seismic data to obtain a velocity model may be considered an inverse problem, where the applied process must determine the subsurface velocity model that resulted in the recorded seismic data.

The various processes and techniques used to process seismic data to form a velocity model may generally be categorized as either a “data-domain approach”, such as full-waveform inversion (FWI), or an “image-domain approach”, such as migration velocity analysis. Among these processes and techniques to construct a subsurface velocity model from seismic data, FWI is considered the state-of-the-art industry practice. However, FWI suffers because many different velocity models can be formed for a seismic data set. That is, FWI solutions are non-unique. Consequently, an FWI solution is sensitive to aspects of the recorded data, such as the lack of low frequencies, the initial starting model, or the acquisition method and configuration of the seismic survey.

In one aspect, embodiments disclosed herein generally relate to a deep learning (DL)-based framework to construct a velocity model from seismic data. Typically, the construction of a DL model requires a large number of training samples, where each training sample contains a seismic data set and an associated velocity model. In many instances, many training samples are not available and synthetic training samples must be generated, for example, through simulation procedures. Often, DL models developed using synthetic training samples are not robust and do not generalize well to real seismic data sets (i.e., seismic data sets acquired in the field). The failure of DL models developed using synthetic training samples to generalize to real seismic data sets is due, in part, to differences between the synthetically generated seismic data sets and real seismic data sets. For example, a significant difference between synthetic seismic data sets and real seismic data sets is that real seismic data sets experience amplitude variations. As will be described, the DL-based framework disclosed herein is robust to amplitude variations in seismic data sets. As such, the DL-based framework described herein may be applied to real seismic data sets to construct accurate velocity models even in circumstances where the DL model used was created using synthetic training samples.

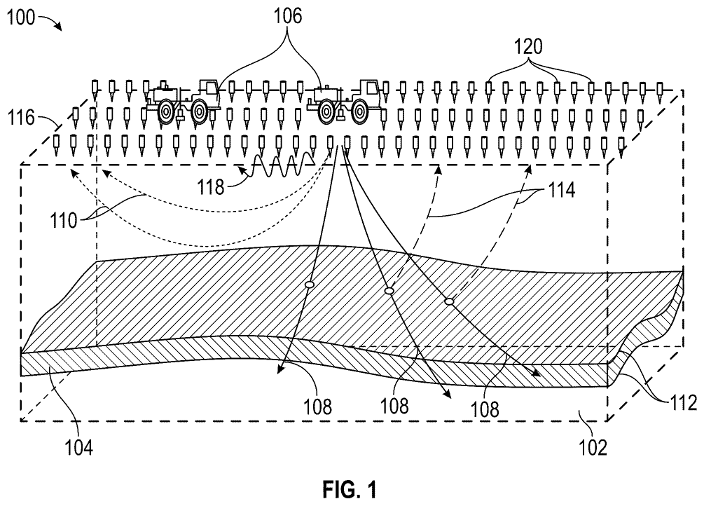

FIG. 1 depicts a seismic survey (100) of a subsurface region of interest (102), which may contain a hydrocarbon reservoir (104). In some cases, the subsurface region of interest (102) may lie beneath a lake, sea, or ocean. In other cases, the subsurface region of interest (102) may lie beneath an area of dry land. The seismic survey (100) may utilize a seismic source (106) that generates radiated seismic waves (108). The type of seismic source (106) may depend on the environment in which it is used, for example on land the seismic source (106) may be a vibroseis truck or an explosive charge, but in water the seismic source (106) may be an airgun. The radiated seismic waves (108) may return to the surface of the earth (116) as refracted seismic waves (110) or may be reflected by geological discontinuities (112) and return to the surface as reflected seismic waves (114). The radiated seismic waves may propagate along the surface as Rayleigh waves or Love waves, collectively known as “ground-roll” (118). Vibrations associated with ground-roll (118) do not penetrate far beneath the surface of the earth (116) and hence are not influenced, nor contain information about, portions of the subsurface region of interest (102) where hydrocarbon reservoirs (104) are typically located. Seismic receivers (120) located on or near the surface of the earth (116) detect reflected seismic waves (114), refracted seismic waves (110) and ground-roll (118).

In accordance with one or more embodiments, the refracted seismic waves (110), reflected seismic waves (114), and ground-roll (118) generated by a single activation of the seismic source (106) are recorded by a seismic receiver (120) as a time-series representing the amplitude of ground-motion at a sequence of discreet sample times. Usually the origin of the time-series, denoted t=0, is determined by the activation time of the seismic source (106). This time-series may be denoted a seismic “trace”. The seismic receivers (120) are positioned at a plurality of seismic receiver locations which we may denote (xᵣ, yᵣ) where x and y represent orthogonal axes on the surface of the earth (116) above the subsurface region of interest (102). Thus, the plurality of seismic traces generated by activations of the seismic source (106) at a single location may be represented as a three-dimensional “3D” volume with axes (xᵣ, yᵣ, t) where (xᵣ, yᵣ) represents the location of the seismic receiver (120) and t denotes the time sample at which the amplitude of ground-motion was measured. The collection of seismic traces is herein referred to as the seismic data set.

However, a seismic survey (100) may include recordings of seismic waves generated by a seismic source (106) sequentially activated at a plurality of seismic source locations denoted (xₛ, yₛ). In some cases, a single seismic source (106) may be activated sequentially at each source location. In other cases, a plurality of seismic sources (106) each positioned at a different location may be activated sequentially. In accordance with one or more embodiments a plurality of seismic sources (106) may be activated during the same time period, or during overlapping time periods.

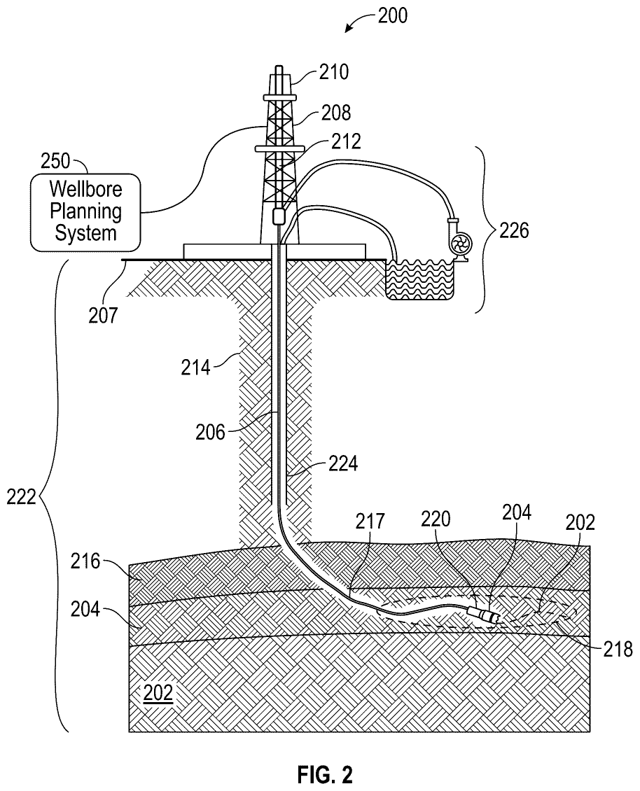

FIG. 2 shows a drilling system (200) in accordance with one or more embodiments. Although the drilling system (200) shown in FIG. 2 is used to drill a wellbore on land, the drilling system (200) may also be a marine wellbore drilling system. The example of the drilling system (200) shown in FIG. 2 is not meant to limit the present disclosure.

As shown in FIG. 2, a wellbore path (202) may be drilled by a drill bit (204) attached by a drillstring (206) to a drill rig located on the surface (207) of the earth. The drill rig may include framework, such as a derrick (208) to hold drilling machinery. The top drive (210) sits at the top of the derrick (208) and provides clockwise torque via the drive shaft (212) to the drillstring (206) in order to drill the wellbore. The wellbore may traverse a plurality of overburden (214) layers and one or more cap-rock (216) layers to a hydrocarbon reservoir (104) within the subsurface region of interest (102). The wellbore path (202) may be a curved wellbore path, or a straight wellbore path. All or part of the wellbore path (202) may be vertical, and some wellbore paths may be deviated or have horizontal sections.

Prior to the commencement of drilling, a wellbore plan may be generated. The wellbore plan may include a starting surface location of the wellbore, or a subsurface location within an existing wellbore, from which the wellbore may be drilled. Further, the wellbore plan may include a terminal location that may intersect with the target zone (218) (e.g., a targeted hydrocarbon-bearing formation) and a planned wellbore path (202) from the starting location to the terminal location. In other words, the wellbore path (202) may intersect a previously located hydrocarbon reservoir (104).

Typically, the wellbore plan is generated based on best available information at the time of planning from a geophysical model, geomechanical models encapsulating subsurface stress conditions, the trajectory of any existing wellbores (which it may be desirable to avoid), and the existence of other drilling hazards, such as shallow gas pockets, over-pressure zones, and active fault planes. In accordance with one or more embodiments, the wellbore plan is informed by a velocity model determined from a seismic data set acquired through a seismic survey (100) conducted over the subsurface region of interest (102).

The wellbore plan may include wellbore geometry information such as wellbore diameter and inclination angle. If casing (224) is used, the wellbore plan may include casing type or casing depths. Furthermore, the wellbore plan may consider other engineering constraints such as the maximum wellbore curvature (“dog-log”) that the drillstring (206) may tolerate and the maximum torque and drag values that the drilling system (200) may tolerate.

A wellbore planning system (250) may be used to generate the wellbore plan. The wellbore planning system (250) may comprise one or more computer processors in communication with computer memory containing the geophysical and geomechanical models, the processed seismic data set, information relating to drilling hazards, and the constraints imposed by the limitations of the drillstring (206) and the drilling system (200). The wellbore planning system (250) may further include dedicated software to determine the planned wellbore path (202) and associated drilling parameters, such as the planned wellbore diameter, the location of planned changes of the wellbore diameter, the planned depths at which casing (224) will be inserted to support the wellbore and to prevent formation fluids entering the wellbore, and the drilling mud weights (densities) and types that may be used during drilling the wellbore.

A wellbore (217) may be drilled using a drill rig that may be situated on a land drill site, an offshore platform, such as a jack-up rig, a semi-submersible, or a drill ship. The drill rig may be equipped with a hoisting system, such as a derrick (208), which can raise or lower the drillstring (206) and other tools required to drill the well. The drillstring (206) may include one or more drill pipes connected to form conduit and a bottom hole assembly (BHA) (220) disposed at the distal end of the drillstring (206). The BHA (220) may include a drill bit (204) to cut into subsurface (222) rock. The BHA (220) may further include measurement tools, such as a measurement-while-drilling (MWD) tool and logging-while-drilling (LWD) tool. MWD tools may include sensors and hardware to measure downhole drilling parameters, such as the azimuth and inclination of the drill bit, the weight-on-bit, and the torque. The LWD measurements may include sensors, such as resistivity, gamma ray, and neutron density sensors, to characterize the rock formation surrounding the wellbore (217). Both MWD and LWD measurements may be transmitted to the surface (207) using any suitable telemetry system, such as mud-pulse or wired-drill pipe, known in the art.

To start drilling, or “spudding in” the well, the hoisting system lowers the drillstring (206) suspended from the derrick (208) towards the planned surface location of the wellbore (217). An engine, such as a diesel engine, may be used to supply power to the top drive (210) to rotate the drillstring (206). The weight of the drillstring (206) combined with the rotational motion enables the drill bit (204) to bore the wellbore.

The near-surface is typically made up of loose or soft sediment or rock, so large diameter casing (224), e.g., “base pipe” or “conductor casing,” is often put in place while drilling to stabilize and isolate the wellbore. At the top of the base pipe is the wellhead, which serves to provide pressure control through a series of spools, valves, or adapters. Once near-surface drilling has begun, water or drill fluid may be used to force the base pipe into place using a pumping system until the wellhead is situated just above the surface (207) of the earth.

Drilling may continue without any casing (224) once deeper, or more compact rock is reached. While drilling, a drilling mud system (226) may pump drilling mud from a mud tank on the surface (207) through the drill pipe. Drilling mud serves various purposes, including pressure equalization, removal of rock cuttings, or drill bit cooling and lubrication.

At planned depth intervals, drilling may be paused and the drillstring (206) withdrawn from the wellbore. Sections of casing (224) may be connected and inserted and cemented into the wellbore. Casing string may be cemented in place by pumping cement and mud, separated by a “cementing plug,” from the surface (207) through the drill pipe. The cementing plug and drilling mud force the cement through the drill pipe and into the annular space between the casing and the wellbore wall. Once the cement cures, drilling may recommence. The drilling process is often performed in several stages. Therefore, the drilling and casing cycle may be repeated more than once, depending on the depth of the wellbore and the pressure on the wellbore walls from surrounding rock.

Due to the high pressures experienced by deep wellbores, a blowout preventer (BOP) may be installed at the wellhead to protect the rig and environment from unplanned oil or gas releases. As the wellbore becomes deeper, both successively smaller drill bits and casing string may be used. Drilling deviated or horizontal wellbores may require specialized drill bits or drill assemblies.

A drilling system (200) may be disposed at and communicate with other systems in the well environment. The drilling system (200) may control at least a portion of a drilling operation by providing controls to various components of the drilling operation. In one or more embodiments, the system may receive data from one or more sensors arranged to measure controllable parameters of the drilling operation. As a non-limiting example, sensors may be arranged to measure weight-on-bit, drill rotational speed (RPM), flow rate of the mud pumps (GPM), and rate of penetration of the drilling operation (ROP). Each sensor may be positioned or configured to measure a desired physical stimulus. Drilling may be considered complete when a target zone (218) is reached, or the presence of hydrocarbons is established.

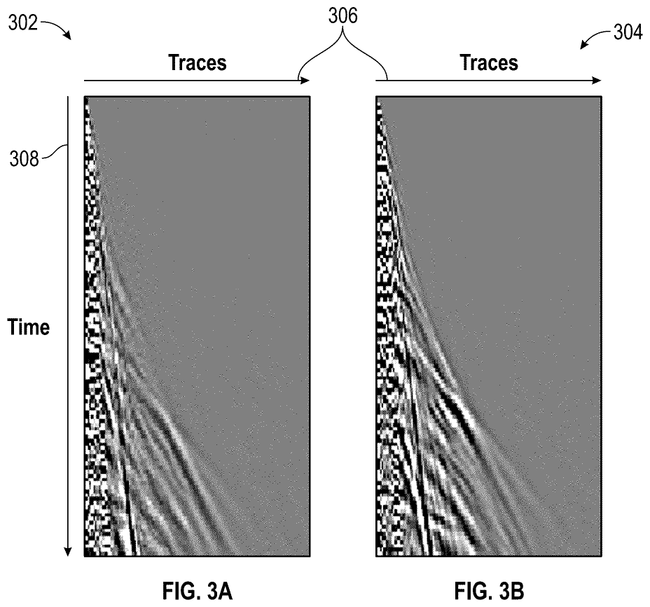

FIGS. 3A and 3B depict real example seismic data sets from neighboring shot gathers; namely, a first example seismic data set (302) and a second example seismic data set (304). The example seismic data sets (302, 304) are each composed of a collection of traces (306) where each trace represents the amplitude of the signal recorded by an associated seismic receiver (120). Often, traces may be referred to as channels. As such, the number of traces (or channels) present in a given seismic data set may be indicated as N_{c}. The spatial distances between each trace, which correspond to the spatial distances between each seismic receiver (120) are known. Each trace (306) (or channel) contains a time series of amplitude values at sampled or discretely recorded times (308). The number of time samples in a seismic data set may be given as Nₜ. The example seismic data sets (302, 304) are considered 2D because, in these examples, the seismic receivers (120) are placed in a single line on the surface, and time, containing information about the depth of subsurface reflectors, is displayed orthogonal to it. However, while FIGS. 3A and 3B demonstrate example 2D seismic data sets (302, 304), this does not constitute a constraint on the dimensionality of a seismic data set. A seismic data set may be 2D or 3D without departing from the scope of this disclosure.

In general, a seismic waveform trace may be written as

$$w ( t ) = A ( t ) {e}^{i θ ( t )} , \qquad ( 1 )$$

where A represents that amplitude of the waveform and θ indicates the phase information, and both the amplitude and phase of the waveform are functions of time t. A seismic trace may be regarded as a convolution between the source function, represented as s, and the impulse response of the subsurface, represented as r. Mathematically, the convolution between source function and impulse response is shown as

$$w = s * r . \qquad ( 2 )$$

While conducting a seismic survey (100), despite efforts to maintain a consistent source function and consistency between gathers, recorded seismic traces present amplitude variations. The amplitude variations are due to changes in impulse response between locations. As stated, the real example seismic data sets (302, 304) of FIGS. 3A and 3B are from neighboring shot gathers. However, as seen, despite originating from neighboring gathers, the real example seismic data sets (302, 304) have significant variations in amplitude. The DL-based framework disclosed herein is robust to amplitude variations in seismic data sets. As such, the DL-based framework described herein may be applied to real seismic data sets to construct accurate velocity models even in circumstances where the DL model used was created using synthetic training samples. The produced velocity model(s) may be used, among other things, to inform other subsurface models and plan wellbore paths in development of a hydrocarbon-bearing well.

For the present discussion, deep learning (DL) may be considered a subset of machine learning (ML). Machine learning (ML), broadly defined, is the extraction of patterns and insights from data. The phrases “artificial intelligence”, “machine learning”, “deep learning”, and “pattern recognition” are often convoluted, interchanged, and used synonymously throughout the literature. This ambiguity arises because the field of “extracting patterns and insights from data” was developed simultaneously and disjointedly among a number of classical arts like mathematics, statistics, and computer science. For consistency, the term machine learning, or machine-learned, will be adopted herein and deep learning (DL) will refer to a subset of machine learning (ML) which deals with so-called “deep” models. For example, a deep model may be a neural network with one or more hidden layers. However, one skilled in the art will recognize that the concepts and methods detailed hereafter are not limited by this choice of nomenclature.

Machine-learned model types may include, but are not limited to, generalized linear models, Bayesian regression, random forests, and deep models such as neural networks, convolutional neural networks, and recurrent neural networks. Machine-learned model types, whether they are considered deep or not, are usually associated with additional “hyperparameters” which further describe the model. For example, hyperparameters providing further detail about a neural network may include, but are not limited to, the number of layers in the neural network, choice of activation functions, inclusion of batch normalization layers, and regularization strength. Commonly, in the literature, the selection of hyperparameters surrounding a model is referred to as selecting the model “architecture”. As such, a DL-based framework consists of methods and systems to transform data, or otherwise determine a quantity, which leverage at least one machine-learned model which may be considered deep. A DL-based framework may include methods and processes to select a machine-learned model type and associated architecture, evaluating said machine-learned model, and using the machine-learned model in a production setting (also known as deployment of the machine-learned model).

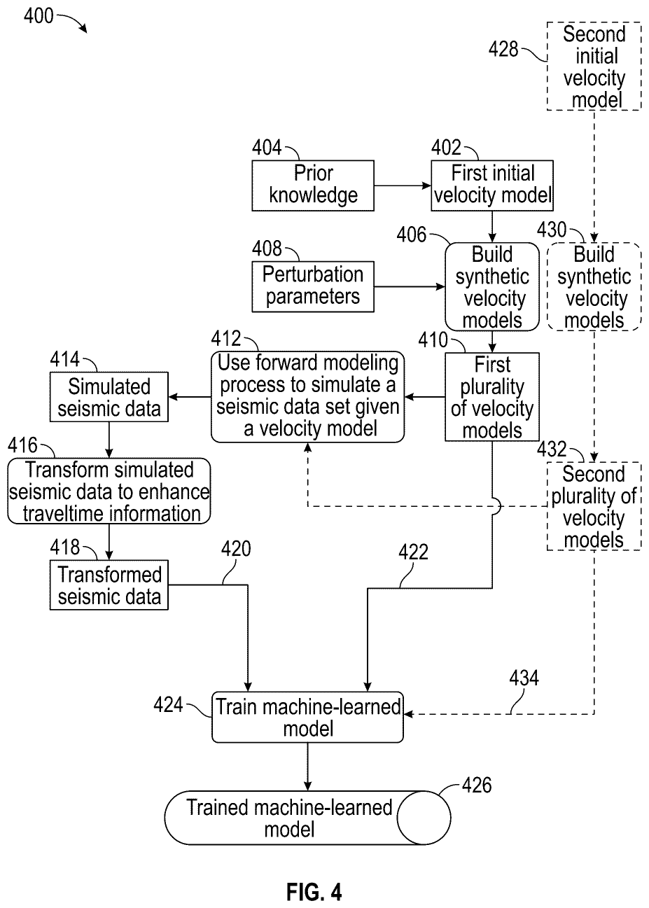

In accordance with one or more embodiments, FIG. 4 depicts a DL-based framework (400) to determine a velocity model from a seismic data set. The goal of the DL-based framework (400) is to train a machine-learned model—specifically, a deep model—to determine a velocity model given seismic data. As will be shown, the DL-based framework (400) produces a trained machine-learned model that is robust to amplitude variations in the seismic data. This, in turn, increases the generalization power of the trained machine-learned model, or the ability of the model to accurately determine a velocity model even using seismic data which differs from that seen during model training. The increased generalization power further allows for accurate velocity model predictions using real seismic data sets even when the machine-learned model is developed using synthetic data.

As depicted in FIG. 4, and in accordance with one or more embodiments, DL-based framework (400) begins with a first initial velocity model (402). The first initial velocity model (402) is a basic velocity model that is intended to generally represent features of expected velocity models. The first initial velocity model (402) is developed with prior knowledge (404) about the subsurface region of interest (102). Prior knowledge (404) may include information about the subsurface region of interest, such as the knowledge about geology, geophysics, and petrophysics.

Generally, a velocity model can be represented as

$$m = m ( x ) , \qquad ( 3 )$$

where x represents a spatial coordinate, such as a location in a subsurface region of interest (102) defined by an x-axis coordinate, a y-axis coordinate, and a depth, d, (e.g., (x,y,d)), and m is a vector indicating the directional velocities at the spatial coordinate x. In some implementations, the subsurface region of interest (102) may be isotropic such that the velocity m at a spatial coordinate may be represented as a scalar.

In accordance with one or more embodiments, synthetic velocity models are generated to train the machine-learned model. To build synthetic velocity models, as depicted in Block 406, the first initial velocity model (402) is perturbed according to perturbation parameters (408). The perturbation parameters (408) may indicate the number of synthetic velocity models to produce and a set of parameters governing the likelihood and magnitude of variation to be applied to the first initial velocity model (402). The resulting perturbed synthetic velocity models are known as a first plurality of velocity models (410).

Continuing with FIG. 4, and in accordance with one or more embodiments, the first plurality of velocity models (410) can be used with a forward modeling process to simulate seismic data sets, one for each velocity model. The forward modeling process simulates the propagation of a seismic wave from one or more seismic sources (106) through a subsurface region of interest (102) to one or more seismic receivers (120). To model the wave propagation, the forward modeling process requires a governing equation such as, for example, the generalized wave equation. The forward modelling process may employ a finite difference method to solve a wave equation, such as the wave equation:

$$( s \frac{{\partial }^{2}}{\partial {t}^{2}} - {∇}^{2} ) p ( x , t ; {x}_{s} ) = f ( t ) δ ( x - {x}_{s} ) . \qquad ( 4 )$$

In EQ. 4, s is a slowness squared vector, where slowness if the reciprocal of velocity, at a spatial coordinate x as given by a supplied velocity model m, ∇² is the Laplacian operator, p represents the seismic wave wavefield, xₛ is the spatial coordinate for a seismic source (106), and ƒ(t) is the signature of the seismic source (106) (e.g., a Ricker wavelet). Thus, seismic data can be simulated at an arbitrary seismic receiver (120) location xₛ. The recorded simulated seismic data may be obtained through the expression:

$$d ( {x}_{r} , t ; {x}_{s} ) = p ( x , t ; {x}_{s} ) δ ( x - {x}_{r} ) . \qquad ( 5 )$$

Thus, the forward modelling process accepts a velocity model of the subsurface region of interest (102) (e.g., one of the velocity models from the first plurality of velocity models (410)) and a survey geometry, and outputs a seismic data set D. Specifically, D represents the recorded data, or the simulated recorded data at each seismic receiver (120). In other words, D is a collection of traces, herein referred to as a seismic data set. The forward modelling process is depicted in Block 412 of FIG. 4. It is emphasized that the forward modelling process is applied to each given velocity model to produce an associated seismic data set. The collection of simulated seismic data sets is referenced as simulated seismic data (414).

As depicted in Block 416, each seismic data set in the simulated seismic data (414) undergoes a transformation to enhance traveltime information in the seismic data (414). In particular, each seismic data set is transformed to remove, or at least mitigate, the effect of the amplitude component A(t) of each trace in the seismic data set. In accordance with one or more embodiments, the transformation is performed by applying a time-variant amplitude-inverse scaling, such as automatic gain control (AGC), to the seismic data set. In other embodiments, the amplitude is deemphasized through trace balancing, which is a time-invariant scaling of amplitudes. The result of Block 416 is transformed seismic data (418), where every seismic data set in the simulated seismic data (414) has been transformed such that traveltime information is enhanced in each seismic data set. Thus, the development of the machine-learned model may be said to be kinematics-driven as kinematic information (traveltime) is prioritized in the seismic data sets.

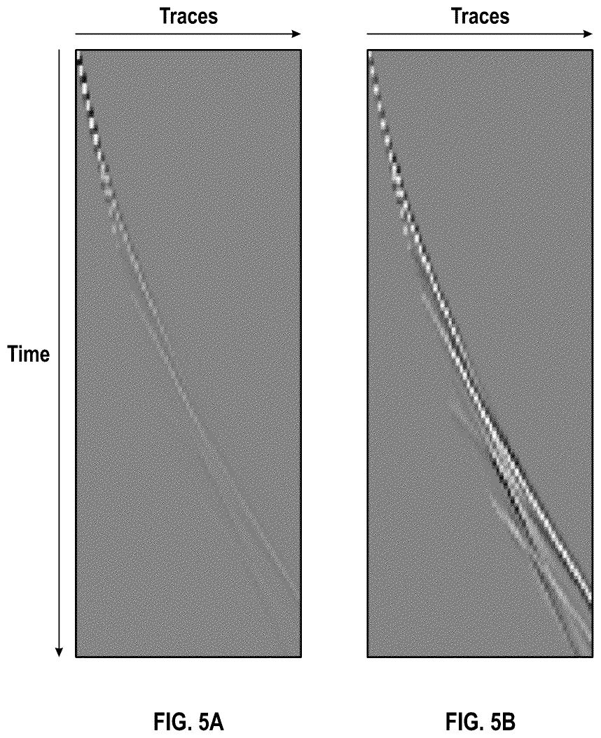

FIGS. 5A and 5B depict the transformation of a given seismic data set, in accordance with one or more embodiments. FIG. 5A depicts an example seismic data set, which may be a simulated seismic data set such as those in the simulated seismic data (414). In the example of FIGS. 5A and 5B, AGC is applied to the example seismic data set of FIG. 5A to transform the example seismic data set to the transformed seismic data set shown in FIG. 5B. The transformation removes, or at least mitigates, amplitude variations in the example seismic data set and boosts kinematic information.

Returning to FIG. 4, generally, training a machine-learned model requires that pairs of inputs and one or more desired targets are passed to the machine-learned model. More details surrounding the training process will be provided below, however, for now it is sufficient to say that during training the machine-learned model “learns” a representative model which maps the received inputs to the associated targets. In the DL-based framework (400), each transformed seismic data set in the transformed seismic data (418) is associated with a velocity model from the first plurality of velocity models (410). A transformed seismic data set may be considered an input to the machine-learned model and the associated velocity model may be considered the desired target. As shown in Block 414, a machine-learned model (such as a deep model) is trained using pairs of inputs (shown with the directed line labelled 420) and targets (shown with the directed line labelled 422). In summary, a machine-learned model is trained (Block 424) using the transformed seismic data (418) and the first plurality of velocity models (410). The resulting machine-learned model is referred to as a trained machine-learned model (426) and is the ultimate product of the DL-based framework (400).

In one or more embodiments, the machine-learned model is trained using additional velocity models and associated simulated seismic data sets. As depicted in FIG. 4, the DL-based framework (400) may be augmented with a second initial velocity model (428). In one or more embodiments, the second velocity model (428) is informed with some prior knowledge regarding a subsurface. Like the first initial velocity model (402), the second initial velocity model (428) may be perturbed to build additional synthetic velocity models, as shown in Block 430. In general, the perturbations applied to the second initial velocity model (428) may follow the perturbation parameters (408) applied to the first initial velocity model (402) or another set of perturbation parameters (not shown). The collection of velocity models developed through perturbations of the second initial velocity model are referred to as the second plurality of velocity models (432). The forward modelling process may be applied to the second plurality of velocity models and appended to the simulated seismic data (414). Likewise, the second plurality of velocity models (432), when used with their associated simulated seismic data sets, may be used to train the machine-learned model in Block 424 as indicated with the directed line labelled 434. While a second initial velocity model (428), from which synthetic velocity models and accompanying seismic data sets may be simulated, is depicted in FIG. 4, in general any number of initial velocity models can be used to generate synthetic training samples for the machine-learned model. That is, a third initial velocity model (and other initial velocity models) may be readily adopted into the framework of FIG. 4 without departing from the scope of this disclosure. In the case where more than one initial velocity model is used to generate synthetic training data, each initial velocity model may be associated with its own prior knowledge and perturbation parameters. In one or more embodiments, many initial velocity models, each with prior knowledge relating to a subsurface representative of a unique geological environment are used to generate synthetic training examples and train the machine-learned model.

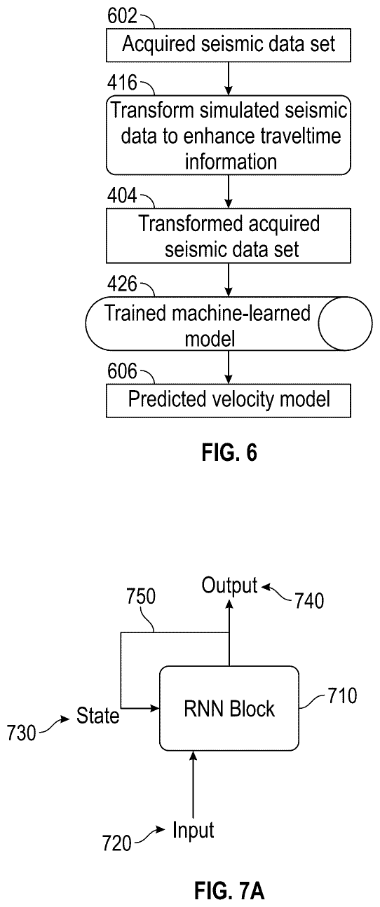

FIG. 6 depicts how the trained machine-learned model (426) is used. First, a new seismic data set is acquired, depicted in FIG. 6 as acquired seismic data set (602). The acquired seismic data set (602) is a real (non-synthetic) seismic data set. For example, the acquired seismic data set (602) may be received from a seismic survey (100). Similar to the processing of the simulated seismic data (414), the acquired seismic data set (602) is transformed to enhance traveltime information and, to promote clarity, the post-transformation seismic data set is referred to as the transformed acquired seismic data set (604). The transformed seismic data set (404) is processed by the trained machine-learned model (426). The trained machine-learned model (426), upon processing the transformed acquired seismic data set (404) produces a predicted velocity model (606).

In accordance with one or more embodiments, the machine-learned model of the DL-based framework (400) is a long short-term memory (LSTM) network, which is a deep model. To best understand a LSTM network, it is helpful to describe the more general recurrent neural network, for which an LSTM may be considered a specific implementation.

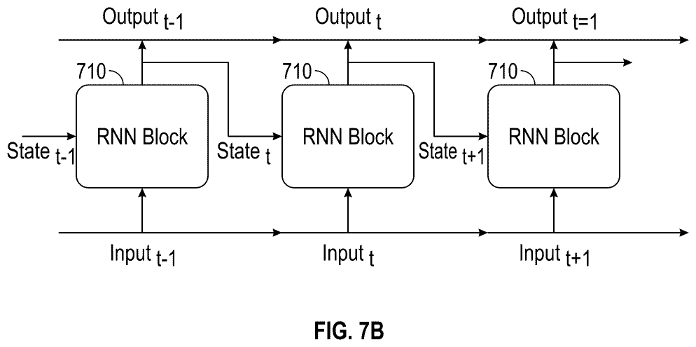

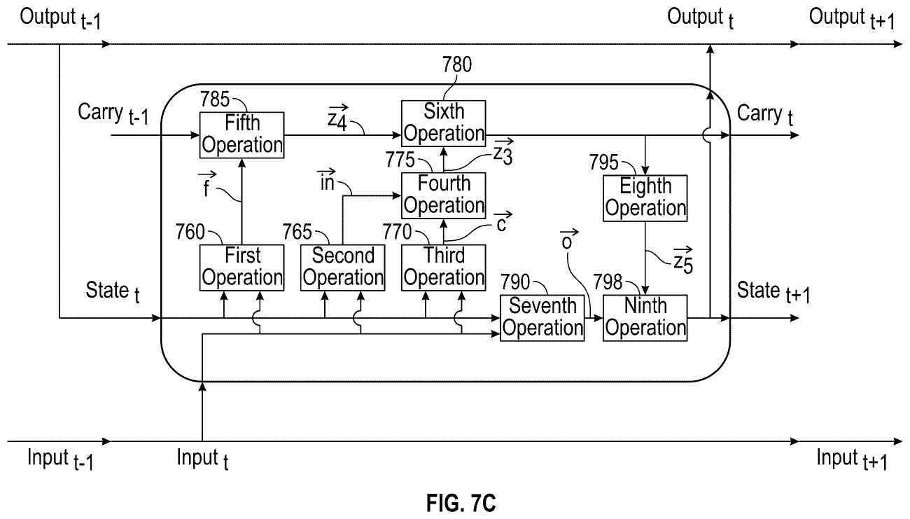

FIG. 7A depicts the general structure of a recurrent neural network (RNN). An RNN is graphically composed of an RNN Block (710) and a recurrent connection (750). The RNN Block may be thought of as a function which accepts an Input (720) and a State (730) and produces an Output (740). Without loss of generality, such a function may be written as

$$Output = RNN Block ( Input , State ) . \qquad ( 6 )$$

The RNN Block (710) generally comprises one or more matrices and one or more bias vectors. The elements of the matrices and bias vectors are commonly referred to as “weights” or “parameters” in the literature such that the matrices may be referenced as weight matrices or parameter matrices without ambiguity. It is noted that for situations with higher dimensional inputs (e.g. inputs with a tensor rank greater than or equal to 2), the weights of an RNN Block (710) may be contained in higher order tensors, rather than in matrices or vectors. For clarity, the present example will consider Inputs (720) as vectors or as scalars such that the RNN Block (710) comprises one or more weight matrices and bias vectors, however, one with ordinary skill in the art will appreciate that this choice does not impose a limitation on the present disclosure. Typically, an RNN Block (710) has two weight matrices and a single bias vector which are distinguished with an arbitrary naming nomenclature. A commonly employed naming convention is to call one weight matrix W and the other U and to reference the bias vector as \vec{b}.

An important aspect of an RNN is that it is intended to process sequential, or ordered, data; for example, a time-series. In the RNN, the Input (720) may be considered a single part of a sequence. As an illustration, consider a sequence composed of Y parts. Each part may be considered an input, indexed by t, such that the sequence may be written as sequence=[input₁, input₂, inputₜ, . . . , input_{Y-1}, input_{Y}]. Each Input (720) (e.g., input₁ of a sequence) may be a scalar, vector, matrix, or higher-order tensor. Recall that a given seismic data set is composed of N_{c} traces (or channels) and Nₜ discrete time steps. In accordance with one or more embodiments, each Input (720) (or element of a sequence) is an array of traces at a single time step. That, each Input (1020) is considered a vector with N_{c} elements.

To process a sequence, an RNN receives the first ordered Input (720) of the sequence, input₁, along with a State (730), and processes them with the RNN Block (710) according to EQ. 6 to produce an Output (740). The Output (740) may be a scalar, vector, matrix, or tensor of any rank. For the present example, the Output (1040) is considered a vector with k elements. The State (730) is of the same type and size as the Output (740) (e.g., a vector with k elements). For the first ordered input, the State (730) is usually initialized with all of its elements set to the value zero. For the second ordered Input (720), input₂, of the sequence, the Input (720) is processed similarly according to EQ. 6, however, the State (730) received by the RNN Block (710) is set to the value of the Output (740) determined when processing the first ordered Input (720). This process of assigning the State (730) the value of the last produced Output (740) is depicted with the recurrent connection (750) in FIG. 7A. All the Inputs (720) in a sequence are processed by the RNN Block (710) in this manner; that is, the State (730) associated with an Input (720) is the Output (740) of the RNN Block (710) produced by the previous Input (720) (with the exception of the first Input (720) in the sequence). In some implementations, each Output (740), one for each Input (710) within a sequence, is stored for later processing and use. In other implementations, only the final Output (740), or the Output (740) which is produced when the Input (720) input_{Y} is processed by the RNN Block (710), is retained.

In greater detail, the process of the RNN Block (710), or EQ. 6, may be generally written as

$$Output = RNN Block ( input , s tate ) = f ( U \cdot state + W \cdot input + \vec{b} ) , \qquad ( 7 )$$

where W, U, and \vec{b} are the weight matrices and bias vector of the RNN Block (710), respectively, and ƒ is an “activation function.” Some functions for ƒ may include the sigmoid function

$$f ( x ) = \frac{1}{1 + {e}^{- x}} ,$$

and rectified linear unit (ReLU) function ƒ(x)=max(0, x), however, many additional functions are commonly employed.

To further illustrate a RNN, a pseudo-code implementation of a RNN is as follows.

RNN Algorithm

Note:
N_{c} = input length
k = output length
W ∈ [symbol]
U ∈ [symbol]
\vec{b} ∈ [symbol]
1: state = [0₁, 0₂, ... , 0ₖ₋₁, 0ₖ]^{T}
2: for input in sequence:
3: \vec{z}₁ = matmul(U, state)
4: \vec{z}₂ = matmul(W, input)
5: output = f(\vec{z}₁ + \vec{z}₂ + \vec{b})
6: state = output

In keeping with the previous examples, both the inputs and the outputs are considered vectors of lengths N_{c} and k, respectively, however, in general, this need not be the case. With the lengths of these vectors defined, the shapes of the weight matrices, bias vector, and State (730) vector may be specified. To begin processing a sequence, the State (730) vector is initialized with values of zero as shown in line 1 of the pseudo-code. Note that in some implementations, the number of inputs contained within a sequence may not be known or may vary between sequences. One with ordinary skill in the art will recognized that an RNN may be implemented without knowing, beforehand, the length of the sequence to be processed. This is demonstrated in line 2 of the pseudo-code by indicating that each input in the sequence will be processed sequentially without specifying the number of inputs in the sequence. Once an Input (720) is received, a matrix multiplication operator is applied between the weight matrix U and the State (730) vector. The resulting product is assigned to the temporary variable \vec{z}₁. Likewise, a matrix multiplication operator is applied between the weight matrix W and the Input (710) with the result assigned to the variable \vec{z}₂. For the present example, due the Input (720) and Output (740) each being defined as vectors, the products in lines 3 and 4 of the pseudo-code may be expressed as matrix multiplications, however, in general, the dot product between the weight matrix and corresponding State (730) or Input (720) may be applied. The Output (740) is determined by summing \vec{z}₁, \vec{z}₂, and the bias vector \vec{b} and applying the activation function ƒ elementwise. The State (730) is set to the Output (740) and the whole process is repeated until each Input (720) in a sequence has been processed.

FIG. 7B depicts an “unrolled” version of the RNN of FIG. 7A. Unrolling the RNN allows one to see how the sequential inputs, indexed by t, produce sequential outputs and how the state is passed through various inputs of the sequence. It is noted that while the “unrolled” depiction shows multiple RNN Blocks (710), these blocks are the same such that they are comprised of the same weight matrices and bias vector.

As previously stated, generally, training a machine-learned model requires that pairs of inputs and one or more targets (i.e., a training dataset) are passed to the machine-learned model. During this process the machine-learned model “learns” a representative model which maps the received inputs to the associated outputs. In the context of an RNN, the RNN receives a sequence, wherein the sequence can be partitioned into one or more sequential parts (Inputs (720) above), and maps the sequence to an overall output, which may also be a sequence. To remove ambiguity and distinguish the overall output of an RNN from any intermediate Outputs (740) produced by the RNN Block (710), the overall output will be referred to herein as a RNN result. In other words, an RNN receives a sequence and returns a RNN result. The training procedure for a RNN comprises assigning values to the weight matrices and bias vector of the RNN Block (710). For brevity, the elements of the weight matrices and bias vector will be collectively referred to as the RNN weights. To begin training the RNN weights are assigned initial values. These values may be assigned randomly, assigned according to a prescribed distribution, assigned manually, or by some other assignment mechanism. Once the RNN weights have been initialized, the RNN may act as a function, such that it may receive a sequence and produce a RNN result. As such, at least one sequence may be propagated through the RNN to produce a RNN result. For training, a training dataset is composed of one or more sequences and desired RNN results, where the desired RNN results represent the “ground truth”, or the true RNN results that should be returned for the given sequences. For clarity, and consistency with previous discussions of machine-learned model training, the desired or true RNN results will be referred to as targets. When processing sequences, the RNN result produced by the RNN is compared to the associated target. The comparison of a RNN result to the target(s) is typically performed by a loss function. As before, other names for this comparison function such as “error function” and “cost function” are commonly employed. Many types of loss functions are available, such as the mean squared error function, however, the general characteristic of a loss function is that the loss function provides a numerical evaluation of the similarity between the RNN result and the associated target(s). The loss function may also be constructed to impose additional constraints on the values assumed by RNN weights, for example, by adding a penalty term, which may be physics-based, or a regularization term. Generally, the goal of a training procedure is to alter the RNN weights to promote similarity between the RNN results and associated targets over the training dataset. Thus, the loss function is used to guide changes made to the RNN weights, typically through a process called “backpropagation through time.”

A long short-term memory (LSTM) network may be considered a specific, and more complex, instance of a recurrent neural network (RNN). FIG. 7C is an unrolled depiction of a LSTM where the internal components of the LSTM are displayed as labelled abstractions. A LSTM, like a RNN, has a recurrent connection, such that the output produced by a single input in a sequence is forwarded as the state to be used with the subsequent input. However, an LSTM also possesses another “state-like” data structure commonly referred to as the “carry.” The carry, like the state and input may be a scalar, vector, matrix, or tensor of any rank depending on the context of the application. Like unto the description of the RNN, for simplicity, the carry will be considered a vector in the following discussion of the LSTM. The LSTM receives an input, state, and carry and produces an output and a new carry. The output and the new carry are passed to the LSTM as the state and carry for the subsequent input. This sequential process, indexed by t, may be described functionally as

$$( {output}_{t} , {carry}_{t} ) = LSTM Block ( {input}_{t} , {carry}_{t - 1} , {state}_{t} ) = LSTM Block ( {input}_{t} , {carry}_{t - 1} , {output}_{t - 1} ) . \qquad ( 8 )$$

where the LSTM Block, like the RNN Block, comprises one or more weight matrices and bias vectors and the processing steps necessary to transform an input, state, and carry to an output and new carry.

LSTMs may be configured in a variety of ways, however, the processes depicted in FIG. 7C are the most common. As shown in FIG. 7C, an LSTM Block receives an input (inputₜ), a state (stateₜ), and a carry (carryₜ₋₁). Again, assuming that the inputs, carry, and outputs are all vectors, the weights of the LSTM Block may be considered to reside in eight matrices and four bias vectors. These matrices and vectors are conventionally named Wᵢ, Uᵢ, W_{ƒ}, U_{ƒ}, W_{c}, U_{c}, Wₒ, Uₒ and \vec{b}ᵢ, \vec{b}_{ƒ}, \vec{b}_{c}, \vec{b}ₒ, respectively. The processes of the LSTM Block are as follows. Block 760 represents the following first operation

$$\vec{f} = {a}_{1} ( {U}_{f} \cdot {state}_{t} + {W}_{f} \cdot {input}_{t} + {\vec{b}}_{f} ) , \qquad ( 9 )$$

where a₁ is an activation function applied elementwise to the result of the parenthetical expression and the resulting vector is \vec{ƒ}. Block 765 implements the following second operation

$$\vec{ι} = {a}_{2} ( {U}_{i} \cdot {state}_{t} + {W}_{i} \cdot {input}_{t} + {\vec{b}}_{i} ) , \qquad ( 10 )$$

where a₂ is an activation function which may be the same or different to a₁ and is applied elementwise to the result of the parenthetical expression. The resulting vector is \vec{i}. Block 770 implements the following third operation

$$\vec{c} = {a}_{3} ( {U}_{c} \cdot {state}_{t} + {W}_{c} \cdot {input}_{t} + {\vec{b}}_{c} ) , \qquad ( 11 )$$

where a₃ is an activation function which may be the same or different to either a₁ or a₂ and is applied elementwise to the result of the parenthetical expression. The resulting vector is \vec{c}. In block 775, vectors \vec{i} and \vec{c} are multiplied according to a fourth operation

$${\vec{z}}_{3} = \vec{ι} ⊙ \vec{c} , \qquad ( 12 )$$

where ⊙ indicates the Hadamard product (i.e., elementwise multiplication). Likewise, in block 785 the carry vector from the previous sequential input (carryₜ₋₁) vector and the vector \vec{ƒ} are multiplied according to a fifth operation

$${\vec{z}}_{4} = {carry}_{t - 1} ⊙ \vec{f} . \qquad ( 13 )$$

The results of the operations of blocks 775 and 785 (\vec{z}₃ and \vec{z}₄, respectively) are added together in block 780, a sixth operation, to form the new carry (carryₜ);

$${carry}_{t} = {\vec{z}}_{3} + {\vec{z}}_{4} . \qquad ( 14 )$$

In block 790, the current input and state vectors are processed according to a seventh operation

$$\vec{o} = {a}_{4} ( {U}_{o} \cdot {state}_{t} + {W}_{o} \cdot {input}_{t} + {\vec{b}}_{o} ) , \qquad ( 15 )$$

where a₄ is an activation function which may be unique or identical to any other used activation function and is applied elementwise to the result of the parenthetical expression. The result is the vector \vec{o}. In block 795, an eighth operation, the new carry (carryₜ) is passed through an activation function a₅. The activation a₅ is usually the hyperbolic tangent function but may be any known activation function. The eighth operations (block 795) may be represented as

$${\vec{z}}_{5} = {a}_{5} ( {carry}_{t} ) . \qquad ( 16 )$$

Finally, the output of the LSTM Block (outputₜ) is determined in block 798 by taking the Hadamard product of \vec{z}₅ and \vec{o}, a ninth operation shown mathematically as

$${output}_{t} = {\vec{z}}_{5} ⊙ \vec{o} . \qquad ( 17 )$$

The output of the LSTM Block is used as the state vector for the subsequent input. Again, as in the case of the RNN, the outputs of the LSTM Block applied to a sequence of inputs may be stored and further processed or, in some implementations, only the final output is retained. While the processes of the LSTM Block described above used vector inputs and outputs, it is emphasized that an LSTM network may be applied to sequences of any dimensionality. In these circumstances the rank and size of the weight tensors will change accordingly. One with ordinary skill in the art will recognized that there are many alterations and variations that can be made to the general LSTM structure described herein, such that the description provided does not impose a limitation on the present disclosure.

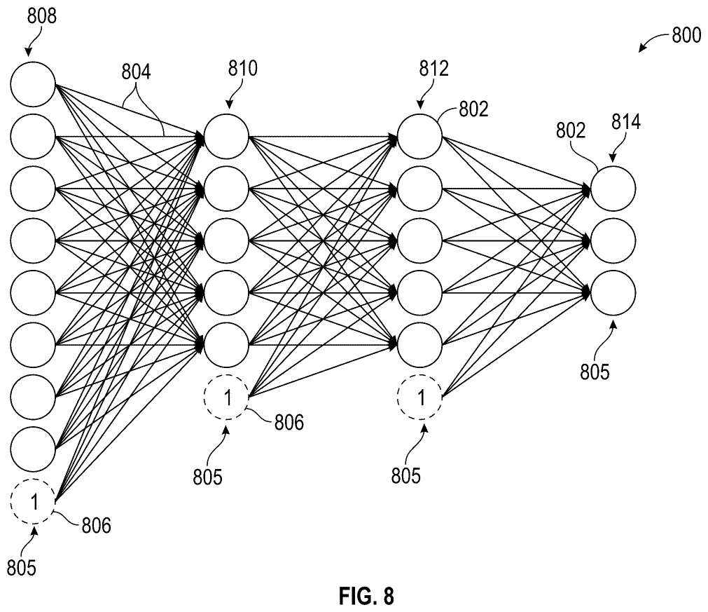

In accordance with one or more embodiments, the RNN result, or the final result of an LSTM, may be further processed with a neural network. A diagram of a neural network is shown in FIG. 8. At a high level, a neural network (800) may be graphically depicted as being composed of nodes (802), where here any circle represents a node, and edges (804), shown here as directed lines. The nodes (802) may be grouped to form layers (805). FIG. 8 displays four layers (808, 810, 812, 814) of nodes (802) where the nodes (802) are grouped into columns, however, the grouping need not be as shown in FIG. 8. The edges (804) connect the nodes (802). Edges (804) may connect, or not connect, to any node(s) (802) regardless of which layer (805) the node(s) (802) is in. That is, the nodes (802) may be sparsely and residually connected. A neural network (800) will have at least two layers (805), where the first layer (808) is considered the “input layer” and the last layer (814) is the “output layer.” Any intermediate layer (810, 812) is usually described as a “hidden layer.” A neural network (800) may have zero or more hidden layers (810, 812) and a neural network (800) with at least one hidden layer (810, 812) may be described a “deep” neural network or a “deep learning method.” In general, a neural network (800) may have more than one node (802) in the output layer (814). In this case the neural network (800) may be referred to as a “multi-target” or “multi-output” network.

Nodes (802) and edges (804) carry additional associations. Namely, every edge is associated with a numerical value. The edge numerical values, or even the edges (804) themselves, are often referred to as “weights” or “parameters” and are analogous to the weights of an RNN. While training a neural network (800), numerical values are assigned to each edge (804). Additionally, every node (802) is associated with a numerical variable and an activation function. Activation functions are not limited to any functional class, but traditionally follow the form

$$A = f ( {\sum }_{i ∈ ( incoming )} [ {( node value )}_{i} {( edge value )}_{i} ] ) , \qquad ( 18 )$$

where i is an index that spans the set of “incoming” nodes (802) and edges (804) and ƒ is a user-defined function. Incoming nodes (802) are those that, when viewed as a graph (as in FIG. 8), have directed arrows that point to the node (802) where the numerical value is being computed. Some functions for ƒ may include the linear function ƒ(x)=x, sigmoid function

$$f ( x ) = \frac{1}{1 + {e}^{- x}} ,$$

and rectified linear unit (ReLU) function ƒ(x)=max(0,x), however, many additional functions are commonly employed. Every node (802) in a neural network (800) may have a different associated activation function. Often, as a shorthand, activation functions are described by the function ƒ by which it is composed. That is, an activation function composed of a linear function ƒ may simply be referred to as a linear activation function without undue ambiguity.

When the neural network (800) receives a network input (e.g., the final output of an LSTM), the network input is propagated through the network according to the activation functions and incoming node (802) values and edge (804) values to compute a value for each node (802). That is, the numerical value for each node (802) may change for each received input. Occasionally, nodes (802) are assigned fixed numerical values, such as the value of 1, that are not affected by the input or altered according to edge (804) values and activation functions. Fixed nodes (802) are often referred to as “biases” or “bias nodes” (606), displayed in FIG. 8 with a dashed circle.

In some implementations, the neural network (800) may contain specialized layers (805), such as a normalization layer, or additional connection procedures, like concatenation. One skilled in the art will appreciate that these alterations do not exceed the scope of this disclosure.

As noted, the training procedure for the neural network (800) comprises assigning values to the edges (804). The training procedure for the neural network (800) is substantially similar to the training process for an RNN (or LSTM), where initial values are assigned the edges (804) and these values are updated via backpropagation according to a loss function. When a neural network (800) receives as a network input the RNN result (or final output of an LSTM), the neural network (800) is often considered part of the RNN (or LSTM). In other words, a RNN (or LSTM) may include a neural network (800). It is noted that when a RNN (or LSTM) includes a neural network (800), the weights and edge (804) values are learned together through a joint training process. A machine-learned model may be composed of both an RNN (e.g., a LSTM) and a neural network (800) and this machine-learned model may be referenced simply as a RNN (or LSTM) with implicit inclusion of the neural network (800).

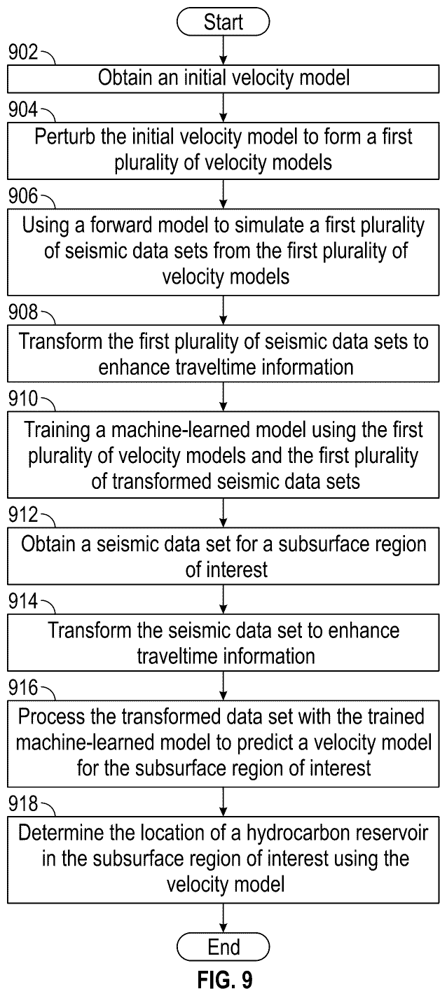

In accordance with one or more embodiments, FIG. 9 depicts a flowchart outlining the steps of the DL-based framework (400) and using the resulting trained machine-learned model (426) to determine a velocity model from seismic data. As illustrated in Block 902 of FIG. 9, first, an initial velocity model is obtained. This model may be informed by some prior knowledge relating to one or more subsurface regions of interest where accurate velocity models are desired. As shown in Block 904, the initial velocity model is perturbed to form a first plurality of velocity models. The procedure for perturbing the initial velocity model may be controlled by a variety of perturbation parameters (408). The perturbation parameters (408) may include the number of subsurface layers, the thicknesses of the layers, and the distribution of velocities in each layer. For example, a velocity value in each layer may be randomly assigned within a pre-defined value range based on the initial velocity model and which makes geological sense while incorporating prior knowledge (404). In Block 906, a forward model is used to simulate a first plurality of seismic data sets from the first plurality of velocity models. The forward modeling process simulates the propagation of a seismic wave from one or more seismic sources (106) through a subsurface region of interest (102) to one or more simulated seismic receivers (120). The forward modelling process accepts the first plurality of velocity models and returns a first plurality of seismic data sets. Each seismic data set represents the recorded data, or the simulated recorded data at each simulated seismic receiver (120). In other words, each simulated seismic data set is a collection of traces, where each trace is a record in time of the amplitude of simulated ground motion. In Block 908, the first plurality of seismic data sets is transformed to enhance traveltime information. In one or more embodiments, the transformation is done using an AGC technique to reduce, or eliminate amplitude variations in the seismic data sets.

A machine-learned model is trained using the first plurality of velocity models and the first plurality of transformed seismic data sets, as shown in Block 910. Training the machine-learned model may encompass splitting the seismic data set and velocity model pairs into training, validation, and test sets. In accordance with one or more embodiments, the machine-learned model is trained using the training set and the hyperparameters of the machine-learned model are tuned by evaluating the machine-learned model on the validation set. Further, the generalization performance of the machine-learned model may be estimated by evaluating the model on the test set. In some implementations, the validation set and test set are the same. Further, one with ordinary skill in the art will appreciate that other common training procedures and techniques, such as cross-validation, may be employed without exceeding the scope of the present disclosure. In accordance with one or more embodiments, the seismic data set and velocity model pairs are split into training, validation, and test sets such that there is a balanced representation of velocity models between each respective set. Sets of velocity models may be compared for similarity through statistical descriptors such as the distribution (mean, standard deviation) of the velocity models contained within a set.

Keeping with FIG. 9, the result of Block 910 is a trained machine-learned model capable of accepting a transformed seismic data set and producing a velocity model. As depicted in Block 912, a seismic data set for a subsurface region of interest is obtained. For example, the seismic data set may be acquired using a seismic survey (100). In Block 914, the seismic data set is transformed to enhance traveltime information. The transformation applied in Block 914 is the same as that applied to the synthetic seismic data sets in Block 908. As depicted in Block 916, the transformed seismic data set is processed with the trained machine-learned model, produced in Block 910, to predict a velocity model for the subsurface region of interest corresponding to the seismic data set. The velocity model may be used to inform subsurface models and/or oil and gas field planning activities. In Block 916, the location of a hydrocarbon reservoir is determined using, at least in part, the predicted velocity model for the subsurface region of interest.

While the various blocks in FIG. 9 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

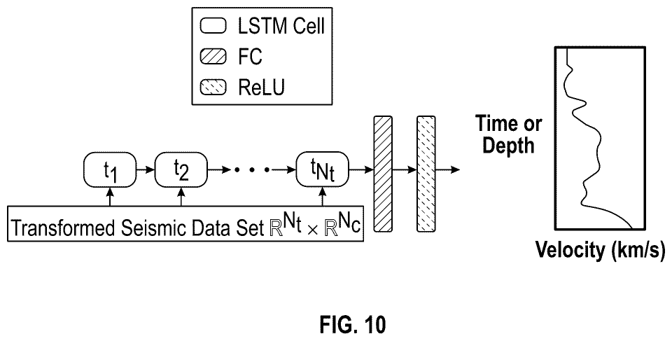

FIGS. 10-12 depict machine-learned model architecture in accordance with one or more embodiments and further show results of the machine-learned model to predict velocity models from seismic data sets. In the following examples, for clarity, the subsurface region of interest is modelled in a single dimension. Mathematically, for a one-dimensional model, a velocity model may be represented with a reduced version of EQ. 3 as

$$v = m ( d )$$

$$or v = m ( t ) ,$$

where v is the scalar velocity (isotropic) which may be related to either a depth d in the subsurface region of interest or a time t (e.g., converted from d via depth-to-time conversion). In general, the machine-learned model may be configured to predict velocity models in either the temporal or spatial domain without departing from the scope of this disclosure. Upon receiving an initial velocity model, a first plurality of velocity models is generated through perturbations.

As shown in FIG. 10, the machine-learned model is a LSTM network. The LSTM network depicted in FIG. 10 accepts, as a sequence, a transformed seismic data set (i.e, a seismic data set with enhanced traveltime information). An input to the LSTM, or a sequential part of the sequence, is a vector of seismic data values for all available channels (or traces) at a given time. In the present example, the overall output of the LSTM is passed to a fully connected (FC) layer with a ReLU activation function. The FC layer with ReLU activation is analogous to a single-layered neural network (800) with a ReLU activation function. Thus, in accordance with one or more embodiments, the FC layer and activation function may be considered part of the LSTM network. The output of the LSTM network (or machine-learned model) is a velocity model, as shown in FIG. 10. The machine-learned model may be configured such that the produced velocity model relates velocities to either depth or the time. Further, in some embodiments, the machine-learned model may be trained, or otherwise configured, to implicitly perform a conversion between time and depth representations.

For the present example, the loss function employed is

$$L = {‖ y - \hat{y} ‖}_{p} + α {‖ ∇ \hat{y} ‖}_{p} + β {‖ \hat{y} ‖}_{p} , \qquad ( 19 )$$

where y is the true (or target) velocity model, ŷ is the predicted velocity model determined by a machine-learned model, and the ∥·∥ₚ operator indicates a mathematical norm of order p, where p is a hyperparameter. The term ∥y−ŷ∥ₚ quantifies the difference, or error, between the predicted velocity model and the true velocity model. The expression ∥∇ŷ∥ₚ quantifies the gradient of the predicted velocity model. Predicted velocity models with abrupt changes in velocity through the depth of the subsurface region of interest will result in a relatively large value for ∥∇ŷ∥ₚ. Likewise. ∥ŷ∥ₚ quantifies the overall magnitude of the velocities throughout the depth of the subsurface region of interest as predicted by the machine-learned model. Because, conventionally, loss functions are sought to be minimized, the latter two terms act as regularization terms where predicted velocity models with large gradients or large velocity values are penalized. α and β are hyperparameters and their values indicate the regularization strength of their associated terms. For the present example, the following values were used for the hyperparameters: p=1, α=1e−4 and β=1e−4.

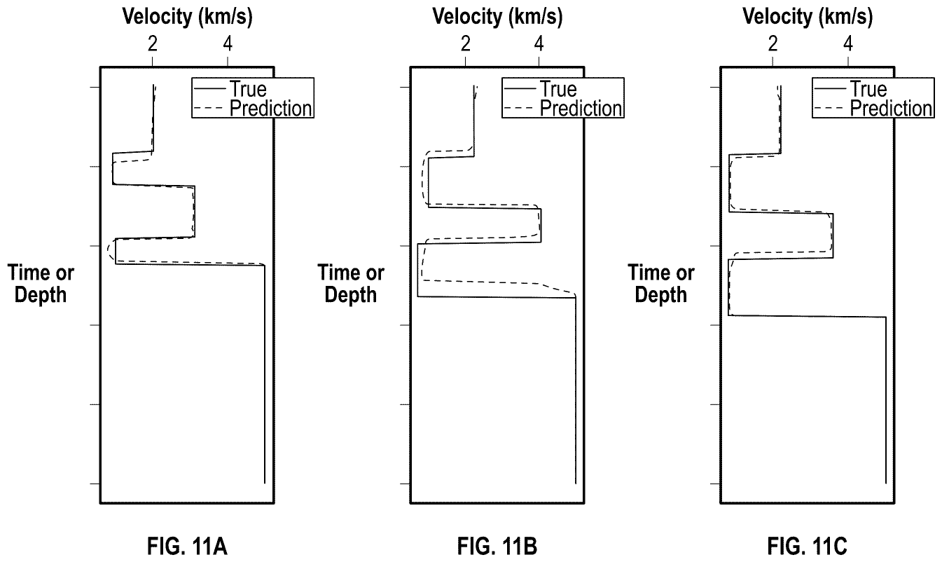

FIGS. 11A-11C depict comparisons of predicted velocity models, predicted using the trained machine-learned model of FIG. 10, to the actual velocity models. The velocity models shown in FIGS. 11A-11C were not used during training of the machine-learned model and thus represent the generalization error of the machine-learned model. As seen, each of the predicted velocity models accurately reflects its associated true velocity model.

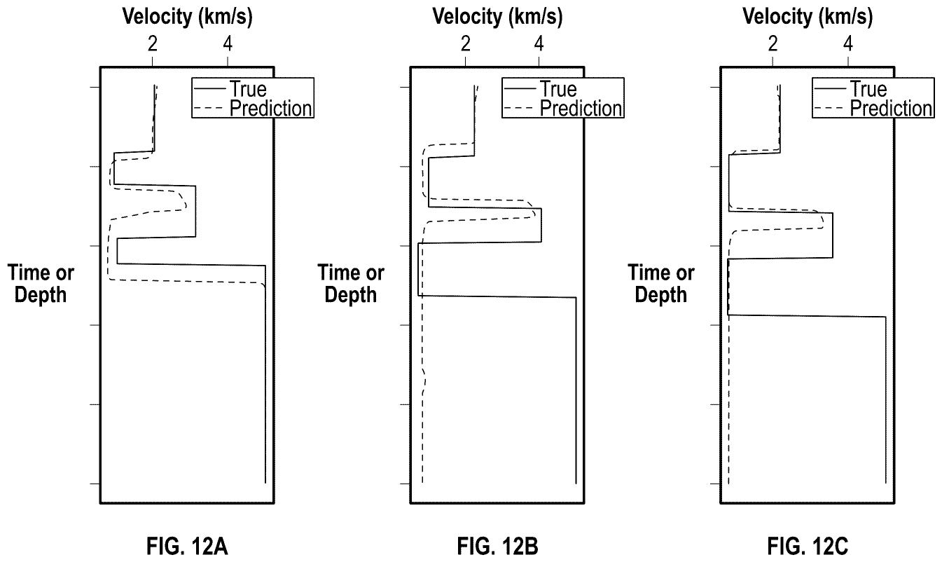

In contrast, FIGS. 12A-12C depict the same velocity models of FIGS. 11A-11C, however, the machine-learned model was trained and implemented while omitting the transformation steps (Block 908 and Block 914). As seen, the predicted velocity models vary wildly and to not accurately represent the true velocity models.

As stated, the examples of FIGS. 10-12 uses one-dimensional velocity models. However, one with ordinary skill in the art will recognized that the DL-based framework (400) and the associated method and processes described herein are not limited to one-dimensional cases. That is, the DL-based framework (400) and the produced machine-learned model may operate on 2D or 3D seismic data to predict 2D or 3D velocity models.

Embodiments of the present disclosure may provide at least one of the following advantages. In accordance with one or more embodiments, the DL-based framework (400) described herein produces a machine-learned model that may determine a velocity model from seismic data. The machine-learned model is robust and may generalize to real (or field) seismic data sets even when trained using synthetic data due to the transformation of the seismic data to enhance traveltime information.

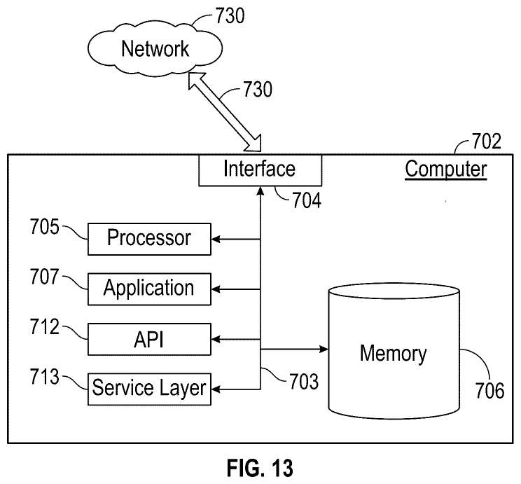

FIG. 13 further depicts a block diagram of a computer system (1302) used to provide computational functionalities associated with described algorithms, methods, functions, processes, flows, and procedures as described in this disclosure, according to one or more embodiments. The illustrated computer (1302) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (1302) may include a computer that includes an input device, such as a keypad, keyboard, touch screen, or other device that can accept user information, and an output device that conveys information associated with the operation of the computer (1302), including digital data, visual, or audio information (or a combination of information), or a GUI.

The computer (1302) can serve in a role as a client, network component, a server, a database or other persistency, or any other component (or a combination of roles) of a computer system for performing the subject matter described in the instant disclosure. In some implementations, one or more components of the computer (1302) may be configured to operate within environments, including cloud-computing-based, local, global, or other environment (or a combination of environments).

At a high level, the computer (1302) is an electronic computing device operable to receive, transmit, process, store, or manage data and information associated with the described subject matter. According to some implementations, the computer (1302) may also include or be communicably coupled with an application server, e-mail server, web server, caching server, streaming data server, business intelligence (BI) server, or other server (or a combination of servers).

The computer (1302) can receive requests over network (1330) from a client application (for example, executing on another computer (1302) and responding to the received requests by processing the said requests in an appropriate software application. In addition, requests may also be sent to the computer (1302) from internal users (for example, from a command console or by other appropriate access method), external or third-parties, other automated applications, as well as any other appropriate entities, individuals, systems, or computers.

Each of the components of the computer (1302) can communicate using a system bus (1303). In some implementations, any or all of the components of the computer (1302), both hardware or software (or a combination of hardware and software), may interface with each other or the interface (1304) (or a combination of both) over the system bus (1303) using an application programming interface (API) (1312) or a service layer (1313) (or a combination of the API (1312) and service layer (1313). The API (1312) may include specifications for routines, data structures, and object classes. The API (1312) may be either computer-language independent or dependent and refer to a complete interface, a single function, or even a set of APIs. The service layer (1313) provides software services to the computer (1302) or other components (whether or not illustrated) that are communicably coupled to the computer (1302). The functionality of the computer (1302) may be accessible for all service consumers using this service layer. Software services, such as those provided by the service layer (1313), provide reusable, defined business functionalities through a defined interface. For example, the interface may be software written in JAVA, C++, or other suitable language providing data in extensible markup language (XML) format or another suitable format. While illustrated as an integrated component of the computer (1302), alternative implementations may illustrate the API (1312) or the service layer (1313) as stand-alone components in relation to other components of the computer (1302) or other components (whether or not illustrated) that are communicably coupled to the computer (1302). Moreover, any or all parts of the API (1312) or the service layer (1313) may be implemented as child or sub-modules of another software module, enterprise application, or hardware module without departing from the scope of this disclosure.

The computer (1302) includes an interface (1304). Although illustrated as a single interface (1304) in FIG. 13, two or more interfaces (1304) may be used according to particular needs, desires, or particular implementations of the computer (1302). The interface (1304) is used by the computer (1302) for communicating with other systems in a distributed environment that are connected to the network (1330). Generally, the interface (1304) includes logic encoded in software or hardware (or a combination of software and hardware) and operable to communicate with the network (1330). More specifically, the interface (1304) may include software supporting one or more communication protocols associated with communications such that the network (1330) or interface's hardware is operable to communicate physical signals within and outside of the illustrated computer (1302).

The computer (1302) includes at least one computer processor (1305). Although illustrated as a single computer processor (1305) in FIG. 13, two or more processors may be used according to particular needs, desires, or particular implementations of the computer (1302). Generally, the computer processor (1305) executes instructions and manipulates data to perform the operations of the computer (1302) and any algorithms, methods, functions, processes, flows, and procedures as described in the instant disclosure.

The computer (1302) also includes a memory (1306) that holds data for the computer (1302) or other components (or a combination of both) that can be connected to the network (1330). The memory may be a non-transitory computer readable medium. For example, memory (1306) can be a database storing data consistent with this disclosure. Although illustrated as a single memory (1306) in FIG. 13, two or more memories may be used according to particular needs, desires, or particular implementations of the computer (1302) and the described functionality. While memory (1306) is illustrated as an integral component of the computer (1302), in alternative implementations, memory (1306) can be external to the computer (1302).

The application (1307) is an algorithmic software engine providing functionality according to particular needs, desires, or particular implementations of the computer (1302), particularly with respect to functionality described in this disclosure. For example, application (1307) can serve as one or more components, modules, applications, etc. Further, although illustrated as a single application (1307), the application (1307) may be implemented as multiple applications (1307) on the computer (1302). In addition, although illustrated as integral to the computer (1302), in alternative implementations, the application (1307) can be external to the computer (1302).

There may be any number of computers (1302) associated with, or external to, a computer system containing computer (1302), wherein each computer (1302) communicates over network (1330). Further, the term “client,” “user,” and other appropriate terminology may be used interchangeably as appropriate without departing from the scope of this disclosure. Moreover, this disclosure contemplates that many users may use one computer (1302), or that one user may use multiple computers (1302).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method, comprising:
obtaining a seismic data set for a subsurface region of interest;
transforming the seismic data set to a transformed seismic data set, wherein traveltime information is enhanced in the transformed seismic data set;
processing the transformed seismic data set with a trained machine-learned model to predict a velocity model for the subsurface region of interest; and
determining a location of a hydrocarbon reservoir in the subsurface region of interest using the velocity model.

2. The method of claim 1, further comprising planning a wellbore to penetrate the hydrocarbon reservoir based on the location, wherein the planned wellbore comprises a planned wellbore path.

3. The method of claim 1, wherein the trained machine-learned model comprises a long-short-term-memory network.

4. The method of claim 1, wherein transforming the seismic data set further comprises deemphasizing amplitude variations in the seismic data set.

5. The method of claim 2, further comprising drilling the wellbore guided by the planned wellbore path.

6. The method of claim 4, wherein deemphasizing amplitude variations comprises applying an automatic gain control technique.

7. A computer-implemented method of training a machine-learned model, comprising:
obtaining a first initial velocity model;
perturbing the first initial velocity model to form a first plurality of velocity models;
using a forward model to simulate a first plurality of seismic data sets from the first plurality of velocity models;
transforming the first plurality of seismic data sets to form a first plurality of transformed seismic data sets, wherein traveltime information is enhanced in each of the transformed seismic data sets in the first plurality of transformed seismic data sets;
training a machine-learned model using the first plurality of velocity models and the first plurality of transformed seismic data sets, wherein the machine-learned model is configured to accept transformed seismic data.

8. The method of claim 7, further comprising:
obtaining a second initial velocity model;
perturbing the second initial velocity model to form a second plurality of velocity models;
using the forward model to simulate a second plurality of seismic data sets from the second plurality of velocity models;
transforming the second plurality of seismic data sets to form a second plurality of transformed seismic data sets, wherein traveltime information is enhanced in each of the transformed seismic data sets in the second plurality of transformed seismic data sets;
training the machine-learned model using the second plurality of velocity models and the second plurality of transformed seismic data sets.

9. The method of claim 7,
wherein transforming the first plurality of seismic data sets and transforming the second seismic data sets further comprises:
deemphasizing amplitude variations in each seismic data set in the first plurality of seismic data sets and the second plurality of seismic data sets.

10. The method of claim 7,
wherein the machine-learned model comprises a long-short-term-memory network.

11. The method of claim 7,
wherein the first initial velocity model is perturbed according to a prior knowledge and a plurality of perturbation parameters, wherein the prior knowledge comprises: petrophysical information about a subsurface region of interest.

12. The method of claim 9, wherein the amplitude variations are deemphasized using an automatic gain control technique.

13. A system, comprising:
a first initial velocity model;
a forward modelling procedure;
a machine-learned model;
a drilling system comprising a wellbore planning system;
a computer comprising one or more computer processors and a non-transitory computer readable medium, the computer configured to:
receive a non-synthetic seismic data set for a subsurface region of interest;
perturb the first initial velocity model to form a first plurality of velocity models;
use the forward modelling procedure to simulate a first plurality of seismic data sets from the first plurality of velocity models;
transform the first plurality of seismic data sets to form a first plurality of transformed seismic data sets, wherein traveltime information is enhanced in each of the transformed seismic data sets;
train the machine-learned model using the first plurality of velocity models and the first plurality of transformed seismic data sets, wherein the machine-learned model is configured to accept one or more transformed seismic data sets;
transform the non-synthetic seismic data set to form a non-synthetic transformed seismic data set; and
process the non-synthetic seismic data set with the trained machine-learned model to predict a velocity model for the subsurface region of interest.

14. The system of claim 13,
wherein transforming the first plurality of seismic data sets further comprises:
deemphasizing amplitude variations in each seismic data set in the first plurality of seismic data sets.

15. The system of claim 13,
wherein the machine-learned model comprises a long-short-term-memory network.

16. The system of claim 13, wherein the wellbore planning system is configured to:
determine a location of a hydrocarbon reservoir in the subsurface region of interest using the velocity model.

17. The system of claim 16, the wellbore planning system configured to:
plan a wellbore to penetrate a hydrocarbon reservoir based on the location, wherein the planned wellbore comprises a planned wellbore path.

18. The system of claim 14, wherein the amplitude variations are deemphasized using an automatic gain control technique.

19. The system of claim 13, wherein the computer is further configured to:
obtain a second initial velocity model;
perturb the second initial velocity model to form a second plurality of velocity models;
use the forward model to simulate a second plurality of seismic data sets from the second plurality of velocity models;
transform the second plurality of seismic data sets to form a second plurality of transformed seismic data sets, wherein traveltime information is enhanced in each of the transformed seismic data sets in the second plurality of transformed seismic data sets; and
train the machine-learned model using the second plurality of velocity models and the second plurality of transformed seismic data sets.

20. The system of claim 15,
wherein the first initial velocity model is perturbed according to a prior knowledge and a plurality of perturbation parameters, wherein the prior knowledge comprises: petrophysical information about the subsurface region of interest.
